(19) United States
(12) Patent Application Publication
(10) Pub. No.: US 2012/0092042 A1
(43) Pub. Date: Apr. 19, 2012

(54) SEMICONDUCTOR DEVICE AND SAMPLE-AND-HOLD CIRCUIT

(75) Inventor: Tatsuya Takei, Tokyo (JP)

(73) Assignee: OLYMPUS CORPORATION, Tokyo (JP)

(21) Appl. No.: 13/274,836

(22) Filed: Oct. 17, 2011

(30) Foreign Application Priority Data
Oct. 18, 2010 (JP) P2010-233869

(51) Int. Cl. G11C 27/02; H03K 17/687

(52) U.S. Cl. 327/94; 327/434

(57) ABSTRACT

A semiconductor device includes a MOS transistor switch that controls passage and interruption of a signal by switching between an ON state and an OFF state, a first switch connected between a back gate terminal of the MOS transistor switch and a source terminal of the MOS transistor switch, and a second switch connected between the back gate terminal of the MOS transistor switch and a power supply voltage terminal If the MOS transistor switch is in the ON state, the first switch is in the ON state and the back gate terminal of the MOS transistor switch is connected to the source terminal of the MOS transistor switch. If the MOS transistor switch is in the OFF state, the second switch is in the ON state, and the back gate terminal of the MOS transistor switch is connected to the power supply voltage terminal.

### BACKGROUND OF THE INVENTION

1. Field of the Invention

The present invention relates to a semiconductor device and a sample-and-hold circuit. More specifically, the present invention relates to technology for supporting a small leak current and a low on-resistance.

Priority is claimed on Japanese Patent Application No. 2010-233869, filed Oct. 18, 2010, the content of which is incorporated herein by reference.

2. Description of the Related Art

All patents, patent applications, patent publications, scientific articles, and the like, which will hereinafter be cited or identified in the present application, will hereby be incorporated by reference in their entirety in order to describe more fully the state of the art to which the present invention pertains.

In a CMOS analog integrated circuit, a switched capacitor circuit is used in an on-chip active filter having high frequency accuracy, and a sample-and-hold circuit for retaining an analog value at a specific timing is used. Major parts of the above-described circuits are constituted by a combination of a switch and a capacitor, and a MOS transistor switch is used as the switch.

Here, a switch having characteristics of a resistance value of zero in an ON state and no current flow in an OFF state is ideal as the switch to be used. However, the MOS transistor switch has characteristics in that a resistance value is not low in the ON state and a slight current flows in the OFF state.

In the ON state, the resistance value leads to a variation in a signal voltage. This resistance value and the capacitor form an unnecessary filter. The filter formed here has a significant influence on a pass band of a signal.

On the other hand, a current flowing in the OFF state (or an off-leak current) leads to a variation in a quantity of electric charge accumulated in the capacitor. If a period of time when an electric charge is accumulated and retained in the capacitor is short, the off-leak current does not have a significant influence. However, if a signal is processed at a very low frequency of several tens of Hz or less, a variation in the quantity of electric charge due to the off-leak current becomes large and has a measurable influence.

Japanese Unexamined Patent Application, First Publication No. 2001-273786, which will be hereinafter referred to as Patent Document 1, discloses a method of preventing a variation in a quantity of electric charge of a capacitor due to an off-leak current. FIG. 4 is a view illustrating a circuit configuration shown in Patent Document 1. A circuit shown in FIG. 4 is a sample-and-hold circuit, and includes an NMOS transistor switch TN5A, an NMOS transistor switch TN5B, an operational amplifier 13, an inverter 15, an NMOS transistor switch TN8, a capacitor C5, and a buffer 11.

The NMOS transistor switch TN5A has a drain terminal connected to an input signal Vin and a gate terminal connected to a control signal. The NMOS transistor switch TN5B has a drain terminal connected to a source terminal of the NMOS transistor switch TN5A and a source terminal of the NMOS transistor switch TN8, and a gate terminal connected to the control signal. The operational amplifier 13 has a non-inverting input terminal connected to a source terminal of the NMOS transistor switch TN5B, and an inverting input terminal and an output terminal connected to a drain terminal of the NMOS transistor switch TN8.

The inverter 15 has an input terminal connected to the control signal and an output terminal connected to a gate terminal of the NMOS transistor switch TN8. The NMOS transistor switch TN8 has the drain terminal connected to the output terminal and the inverting input terminal of the operational amplifier 13, the gate terminal connected to an output terminal of the inverter 15, and the source terminal connected to the source terminal of the NMOS transistor switch TN5A and the drain terminal of the NMOS transistor switch TN5B.

The capacitor C5 has one end connected to the source terminal of the NMOS transistor switch TN5B and the non-inverting input terminal of the operational amplifier 13, and the other end connected to GND. The buffer 11 has an input terminal connected to the source terminal of the NMOS transistor switch TN5B and the non-inverting input terminal of the operational amplifier 13, and outputs an output signal Vout.

If the control signal has an H level in the above-described circuit, the NMOS transistor switch TN5A and the NMOS transistor switch TN5B are in the ON state, and the NMOS transistor switch TN8 is in the OFF state. In this state, an input signal Vin is applied to the capacitor C5 through the NMOS transistor switch TNSA and the NMOS transistor switch TN5B. Accordingly, an electric charge determined by the capacitance of the capacitor C5 and the input signal Vin is accumulated in the capacitor C5, and the same signal as the input signal Vin is output as the output signal Vout.

On the other hand, if the control signal has an L level, the NMOS transistor switch TN5A and the NMOS transistor switch TN5B are in the OFF state, and the NMOS transistor switch TN8 is in the ON state. In this state, the input signal Vin is separated from the circuit by the NMOS transistor switch TNSA, and a voltage corresponding to the electric charge accumulated in the capacitor C5 is output as the output signal Vout via the buffer 11. The same voltage as the voltage corresponding to the electric charge accumulated in the capacitor C5 is also applied to the drain terminal of the NMOS transistor switch TN5B via the NMOS transistor switch TN8 by the operational amplifier 13.

Accordingly, the same voltage is applied to the source terminal and the drain terminal of the NMOS transistor switch TN5B, that is, a potential difference is absent between the source terminal and the drain terminal of the NMOS transistor switch TN5B. Thereby, an off-leak current occurring in the NMOS transistor switch TN5B is absent, and therefore a variation in the quantity of electric charge retained in the capacitor C5 according to a retention time may be prevented.

However, in the configuration of Patent Document 1, two switches of the NMOS transistor switch TN5A and the NMOS transistor switch TN5B are present in a signal path in a sampling state, and an on-resistance of the MOS transistor switch becomes higher.

### SUMMARY

The present invention implements a semiconductor device and a sample-and-hold circuit using a MOS transistor switch having a low on-resistance in an ON state and a small off-leak current in an OFF state.

A semiconductor device may include: a MOS transistor switch configured to control passage and interruption of a signal by switching between an ON state and an OFF state; a first switch connected between a back gate terminal of the MOS transistor switch and a source terminal of the MOS transistor switch; and a second switch connected between the back gate terminal of the MOS transistor switch and a power supply voltage terminal. If the MOS transistor switch is in the ON state, then the first switch may be in the ON state and the back gate terminal of the MOS transistor switch may be connected to the source terminal of the MOS transistor switch. If the MOS transistor switch is in the OFF state, then the second switch may be in the ON state and the back gate terminal of the MOS transistor switch may be connected to the power supply voltage terminal.

A semiconductor device may include: a MOS transistor switch configured to control passage and interruption of a signal by switching between an ON state and an OFF state; and a variable voltage source connected to a back gate terminal of the MOS transistor switch. If the MOS transistor switch is in the ON state, then the variable voltage source may output a first voltage to the back gate terminal so that a threshold voltage of the MOS transistor switch becomes lower than when the MOS transistor switch is in the OFF state. If the MOS transistor switch is in the OFF state, then the variable voltage source may output a second voltage to the back gate terminal so that the threshold voltage of the MOS transistor switch becomes higher than when the MOS transistor switch is in the ON state.

A sample-and-hold circuit may include: the semiconductor device; a capacitor configured to accumulate an electric charge corresponding to an input voltage; and an output buffer configured to convert the electric charge accumulated in the capacitor into a voltage. If the MOS transistor switch is in an ON state, then the capacitor may accumulate the electric charge corresponding to the input voltage. If the MOS transistor switch is in an OFF state, then the capacitor may retain the electric charge that has been accumulated in the capacitor.

According to the present invention, it is possible to implement a semiconductor device and a sample-and-hold circuit using a MOS transistor switch having a low on-resistance in an ON state and a small off-leak current in an OFF state by changing a connection destination of a back gate terminal of the MOS transistor switch or changing a voltage to be output to the back gate terminal simultaneously when the ON and OFF states of the MOS transistor switch are switched.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a view illustrating a circuit configuration of a semiconductor device in accordance with the first preferred embodiment of the present invention;

FIG. 2 is a view illustrating a circuit configuration of a sample-and-hold circuit in accordance with the second preferred embodiment of the present invention;

FIG. 3 is a view illustrating a circuit configuration of a sample-and-hold circuit in accordance with the third preferred embodiment of the present invention; and

FIG. 4 is a view illustrating a circuit configuration in accordance with the related art.

### DETAILED DESCRIPTION OF THE PREFERRED EMBODIMENTS

The present invention will be now described herein with reference to illustrative preferred embodiments. Those skilled in the art will recognize that many alternative preferred embodiments can be accomplished using the teaching of the present invention and that the present invention is not limited to the preferred embodiments illustrated for explanatory purpose.

### First Preferred Embodiment

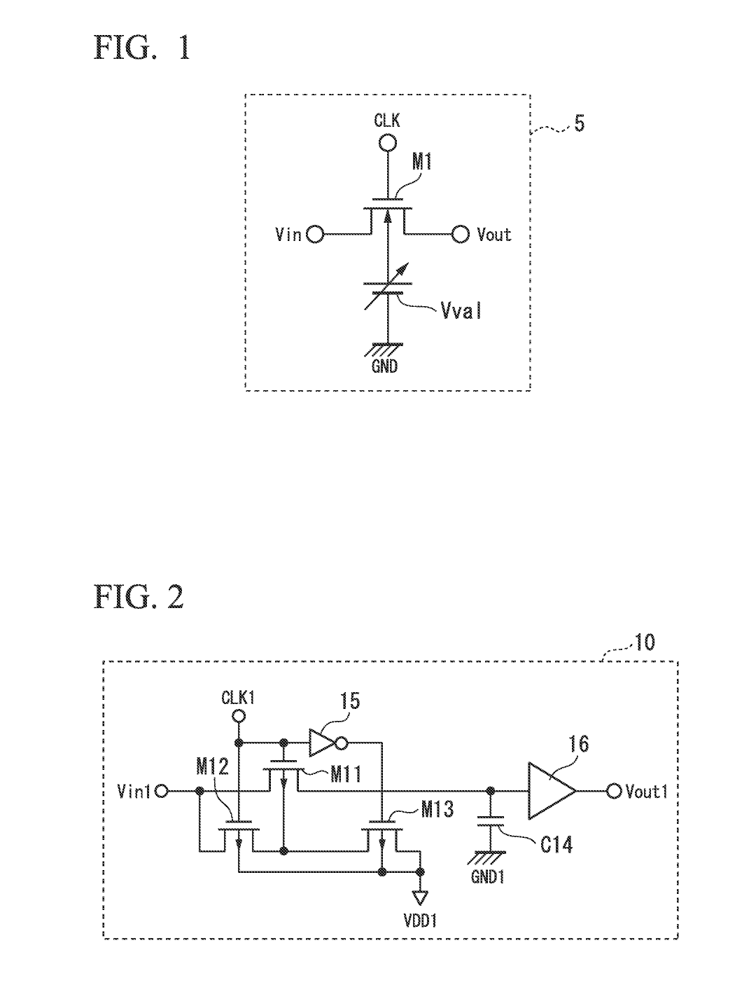

First, a first preferred embodiment of the present invention will be described. FIG. 1 is a view illustrating a circuit configuration of a semiconductor device in accordance with the first preferred embodiment of the present invention. A semiconductor device 5 shown in FIG. 1 includes 4 input/output terminals of a power supply voltage terminal GND, a signal input terminal Vin, a signal output terminal Vout, and a control signal terminal CLK as terminals connected to the outside, and includes an NMOS transistor M1 and a variable voltage source Vval.

The NMOS transistor M1 has a drain terminal connected to the signal input terminal Vin, a gate terminal connected to the control signal terminal CLK, and a source terminal connected to the signal output terminal Vout. The NMOS transistor M1 is a MOS transistor switch that controls passage and interruption of an input signal input from the signal input terminal Vin by switching an ON state and an OFF state. The variable voltage source Vval has one end connected to a back gate terminal of the NMOS transistor M1 and the other end connected to the power supply voltage terminal GND.

Next, an operation of the semiconductor device 5 will be described. The NMOS transistor M1 is in the ON state if an H-level signal is applied to the gate terminal thereof and is in the OFF state if an L-level signal is applied thereto. The variable voltage source Vval outputs the same voltage as a voltage applied to the source terminal of the NMOS transistor M1 if a signal from the control signal terminal CLK has an H level, and outputs a voltage equivalent to a voltage of the power supply voltage terminal GND if the signal from the control signal terminal CLK has an L level.

First, the case where an H-level signal is applied from the control signal terminal CLK will be described. If the H-level signal is applied from the control signal terminal CLK, the NMOS transistor M1 is in the ON state. Simultaneously with a variation of this state, a voltage equivalent to the voltage of the source terminal is applied to the back gate terminal of the NMOS transistor M1. In this state, as compared to a state in which the back gate terminal is connected to the power supply voltage terminal GND, the number of electrons around a gate oxide film is small and a threshold voltage Vth of the NMOS transistor M1 is low. Here, an on-resistance Ron of the MOS transistor is expressed by the following Equation (1).

$$Ron = \frac{1}{μ {C}_{OX} \cdot ( W / L ) \cdot ( VDD - Vth )} \qquad ( 1 )$$

In Equation (1), μ denotes carrier mobility, C_{OX} denotes capacitance per unit area of the gate oxide film, W denotes a gate width of the MOS transistor, L denotes a gate length of the MOS transistor, and VDD denotes an applied power supply voltage. The on-resistance Ron is low if the threshold voltage Vth is low from Equation (1).

Next, the case where an L-level signal is applied from the control signal terminal CLK will be described. If the L-level signal is applied from the control signal terminal CLK, the NMOS transistor M1 is in the OFF state. Simultaneously with a variation of this state, a voltage equivalent to the voltage of the power supply voltage terminal GND is applied to the back gate terminal of the NMOS transistor M1. In this state, as compared to a state in which the back gate terminal is connected to the source terminal, the number of electrons around the gate oxide film is large and the threshold voltage Vth of the NMOS transistor M1 is high. Here, an off-leak current Ileak of the MOS transistor is expressed by the following Equation (2).

$$Ileak = a \cdot exp \{ - \frac{Vth \cdot q}{n \cdot k \cdot T} \} \qquad ( 2 )$$

In Equation (2), a denotes a proportionality coefficient, q denotes the electric charge of an electron, k denotes a Boltzmann coefficient, T is an absolute temperature, and n is an eigenvalue depending on a device taking a value of about 1 to 1.4. The off-leak current Ileak is small if the threshold voltage Vth is high from Equation (2).

As described above, it is possible to implement a MOS transistor switch having the low on-resistance in the ON state and the small off-leak current in the OFF state by varying a voltage to be output to the back gate terminal simultaneously when the ON and OFF states of the MOS transistor M1 are switched, and a semiconductor device using the same.

### Second Preferred Embodiment

Next, a second preferred embodiment of the present invention will be described. FIG. 2 is a view illustrating a circuit configuration of a sample-and-hold circuit in accordance with the second preferred embodiment of the present invention. A sample-and-hold circuit 10 shown in FIG. 2 includes 5 input/output terminals of a power supply voltage terminal VDD1, a power supply voltage terminal GND1, a signal input terminal Vin1, a signal output terminal Vout1, and a control signal terminal CLK1 as terminals connected to the outside, and includes an inverter 15, a PMOS transistor M11, a PMOS transistor M12 (a first switch), a PMOS transistor M13 (a second switch), a capacitor C14 (a capacity), and an amplifier circuit 16 (an output buffer). A circuit including the PMOS transistors M12, M11, and M13 is an example of the semiconductor device of the present invention.

The inverter 15 has an input terminal connected to the control signal terminal CLK1. The PMOS transistor M12 has a drain terminal connected to the signal input terminal Vint, a gate terminal connected to the control signal terminal CLK1, and a back gate terminal connected to the power supply voltage terminal VDD1.

The PMOS transistor Mil has a source terminal connected to the signal input terminal Vin1, a gate terminal connected to the control signal terminal CLK1, and a back gate terminal connected to a source terminal of the PMOS transistor M12. The PMOS transistor M11 is a MOS transistor switch that controls passage and interruption of an input signal input from the signal input terminal Vin by switching the ON state and the OFF state.

The PMOS transistor M13 has a drain terminal connected to the source terminal of the PMOS transistor M12 and the back gate terminal of the PMOS transistor M11, a gate terminal connected to an output terminal of the inverter 15, and a back gate terminal and a source terminal connected to the power supply voltage terminal VDD1.

The capacitor C14 has one end connected to a drain terminal of the PMOS transistor M11 and the other end connected to the power supply voltage terminal GND1. The amplifier circuit 16 has an input terminal connected to the drain terminal of the PMOS transistor M11 and the one end of the capacitor C14, and an output terminal connected to the signal output terminal Vout1.

Next, an operation of the sample-and-hold circuit 10 will be described. The PMOS transistors M11, M12, and M13 are in the OFF state if an H-level signal is applied to the gate terminals thereof, and are in the ON state if an L-level signal is applied thereto.

First, the case where an L-level signal is applied from the control signal terminal CLK1 will be described. If the L-level signal is applied from the control signal terminal CLK1, the PMOS transistors M11 and M12 are in the ON state and the PMOS transistor M13 is in the OFF state. Accordingly, the back gate terminal of the PMOS transistor M11 is connected to the source terminal of the PMOS transistor M11 via the PMOS transistor M12. In this state, as compared to a state in which the back gate terminal is connected to the power supply voltage terminal VDD1, the number of electrons around a gate oxide film is small and a threshold voltage Vth of the PMOS transistor M11 is low. Here, an on-resistance Ron of the MOS transistor is expressed by the following Equation (3).

$$Ron = \frac{1}{μ {C}_{OX} \cdot ( W / L ) \cdot ( VDD - Vth )} \qquad ( 3 )$$

In Equation (3), μ denotes carrier mobility, C_{OX} denotes capacitance per unit area of the gate oxide film, W denotes a gate width of the MOS transistor, L denotes a gate length of the MOS transistor, and VDD denotes an applied power supply voltage. The on-resistance Ron is low if the threshold voltage Vth is low from Equation (3).

If the L-level signal is applied from the control signal terminal CLK1, an input signal input from the signal input terminal Vin1 is applied to the capacitor C14 through the PMOS transistor M11. Accordingly, an electric charge determined by the capacitance of the capacitor C14 and the input signal is accumulated in the capacitor C14.

Next, the case where an H-level signal is applied from the control signal terminal CLK1 will be described. If the H-level signal is applied from the control signal terminal CLK1 the PMOS transistors M11 and M12 are in the OFF state and the PMOS transistor M13 is in the ON state. Accordingly, the back gate terminal of the PMOS transistor M11 is connected to the power supply voltage terminal VDD1 via the PMOS transistor M13.

In this state, as compared to a state in which the back gate terminal is connected to the source terminal, the number of electrons around the gate oxide film is large and the threshold voltage Vth of the PMOS transistor M11 is high. Here, an off-leak current Ileak of the MOS transistor is expressed by the following Equation (4)

$$Ileak = a \cdot exp \{ - \frac{Vth \cdot q}{n \cdot k \cdot T} \} \qquad ( 4 )$$

In Equation (4), a denotes a proportionality coefficient, q denotes the electric charge of an electron, k denotes a Boltzmann coefficient. T is an absolute temperature, and n is an eigenvalue depending on a device taking a value of about 1 to 1.4. The off-leak current Ileak is small if the threshold voltage Vth is high from Equation (4).

If the H-level signal is applied from the control signal terminal CLK1, an input signal input from the signal input terminal Vin1 is separated from the circuit by the PMOS transistors M11 and M12, and a voltage corresponding to an electric charge accumulated and retained in the capacitor C14 is output to the signal output terminal Vout1 via the amplifier circuit 16.

As described above, it is possible to implement a MOS transistor switch having the low on-resistance in the ON state and the small off-leak current in the OFF state by changing a connection destination of the back gate terminal of the PMOS transistor M11 simultaneously when the ON and OFF states of the PMOS transistor M11 are switched, and a semiconductor device using the same. Also, it is possible to implement a sample-and-hold circuit in which a voltage drop occurring in the switch decreases during sampling and an electric charge fluctuation due to a leak current of the switch is small during holding by use of the above-described MOS transistor switch.

### Third Preferred Embodiment

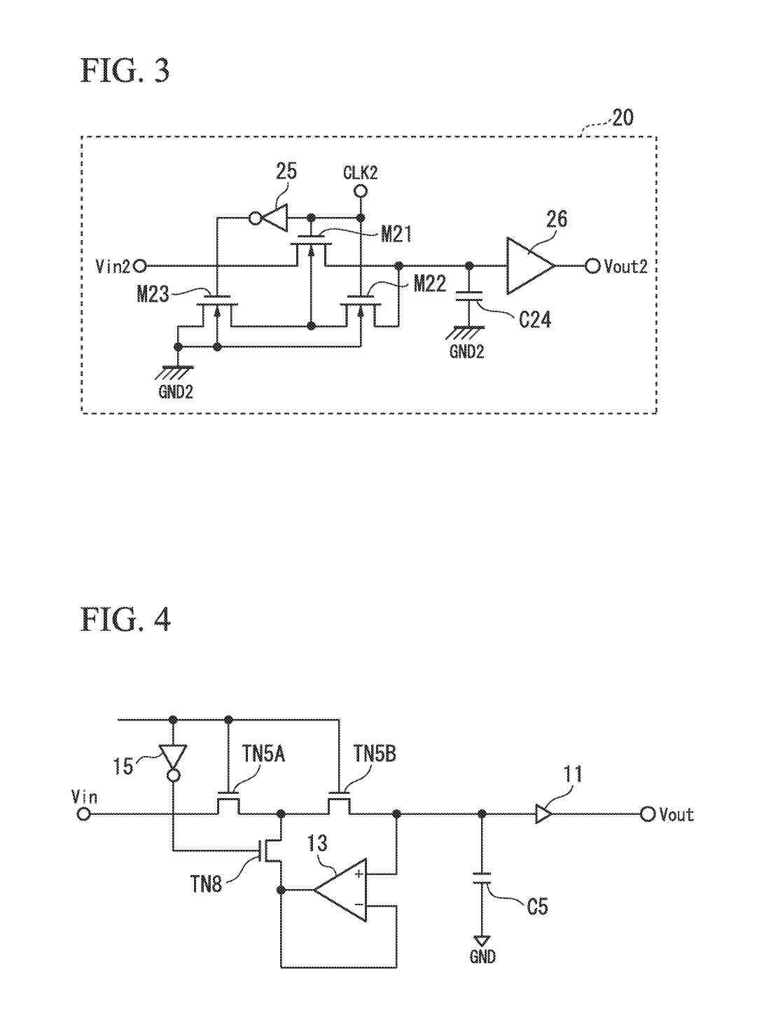

Next, a third preferred embodiment of the present invention will be described. FIG. 3 is a view illustrating a circuit configuration of a sample-and-hold circuit in accordance with the third preferred embodiment of the present invention. A sample-and-hold circuit 20 shown in FIG. 3 includes 4 input/output terminals of a power supply voltage terminal GND2, a signal input terminal Vin2, a signal output terminal Vout2, and a control signal terminal CLK2 as terminals connected to the outside, and includes an inverter 25, an NMOS transistor M21, an NMOS transistor M22 (a first switch), an NMOS transistor M23 (a second switch), a capacitor C24 (a capacity), and an amplifier circuit 26 (an output buffer). A circuit including the NMOS transistors M21, M23, and M22 is an example of the semiconductor device of the present invention.

The inverter 25 has an input terminal connected to the control signal terminal CLK2. The NMOS transistor M21 has a drain terminal connected to the signal input terminal Vin2, a gate terminal connected to the control signal terminal CLK2, and a back gate terminal connected to a drain terminal of the NMOS transistor M23 and a drain ten final of the NMOS transistor M22. The NMOS transistor M21 is a MOS transistor switch that controls passage and interruption of an input signal input from the signal input terminal Vin2 by switching the ON state and the OFF state.

The NMOS transistor M23 has the drain terminal connected to the back gate terminal of the NMOS transistor M21, a gate terminal connected to an output terminal of the inverter 25, and a back gate terminal and a source terminal connected to the power supply voltage terminal GND2. The NMOS transistor M22 has the drain terminal connected to the back gate terminal of the NMOS transistor M21, a gate terminal connected to the control signal terminal CLK2, a back gate terminal connected to the power supply voltage terminal GND2, and a source terminal connected to the source terminal of the NMOS transistor M21.

The capacitor C24 has one end connected to the source terminal of the NMOS transistor M21 and the other end connected to the power supply voltage terminal GND2. The amplifier circuit 26 has an input terminal connected to the source terminal of the NMOS transistor M21 and the one end of the capacitor C24, and an output terminal connected to the signal output terminal Vout2.

Next, an operation of the sample-and-hold circuit 20 will be described. The NMOS transistors M21, M22, and M23 are in the ON state if an H-level signal is applied to the gate terminals thereof, and are in the OFF state if an L-level signal is applied thereto.

First, the case where an H-level signal is applied from the control signal terminal CLK2 will be described. If the H-level signal is applied from the control signal terminal CLK2, the NMOS transistors M21 and M22 are in the ON state and the NMOS transistor M23 is in the OFF state. Accordingly, the back gate terminal of the NMOS transistor M21 is connected to the source terminal of the NMOS transistor M21 via the NMOS transistor M22. In this state, as compared to a state in which the back gate terminal is connected to the power supply voltage terminal GND2, the number of electrons around a gate oxide film is small and a threshold voltage Vth of the NMOS transistor M21 is low. Here, an on-resistance Ron of the MOS transistor is expressed by the following Equation (5).

$$Ron = \frac{1}{μ {C}_{OX} \cdot ( W / L ) \cdot ( VDD - Vth )} \qquad ( 5 )$$

In Equation (5), μ denotes carrier mobility, C_{OX} denotes capacitance per unit area of the gate oxide film, W denotes a gate width of the MOS transistor, L denotes a gate length of the MOS transistor, and VDD denotes an applied power supply voltage. The on-resistance Ron is low if the threshold voltage Vth is low from the above equation.

If the H-level signal is applied from the control signal terminal CLK2, an input signal input from the signal input terminal Vin2 is applied to the capacitor C24 through the NMOS transistor M21. Accordingly, an electric charge determined by the capacitance of the capacitor C24 and the input signal is accumulated in the capacitor C24.

Next, the case where an L-level signal is applied from the control signal terminal CLK2 will be described. If the L-level signal is applied from the control signal terminal CLK2, the NMOS transistors M21 and M22 are in the OFF state and the NMOS transistor M23 is in the ON state. Accordingly, the back gate terminal of the NMOS transistor M21 is connected to the power supply voltage terminal GND2 via the NMOS transistor M23.

In this state, as compared to a state in which the back gate terminal is connected to the source terminal, the number of electrons around the gate oxide film is large and the threshold voltage Vth of the NMOS transistor M21 is high. Here, an off-leak current Ileak of the MOS transistor is expressed by the following Equation (6).

$$Ileak = a \cdot exp \{ - \frac{Vth \cdot q}{n \cdot k \cdot T} \} \qquad ( 6 )$$

In Equation (6), a denotes a proportionality coefficient, q denotes the electric charge of an electron, k denotes a Boltzmann coefficient, T is an absolute temperature, and n is an eigenvalue depending on a device taking a value of about 1 to 1.4. The off-leak current Ileak is small if the threshold voltage Vth is high from the above equation.

If the L-level signal is applied from the control signal terminal CLK2, an input signal input from the signal input terminal Vin2 is separated from the circuit by the NMOS transistor M21, and a voltage corresponding to an electric charge accumulated and retained in the capacitor C24 is output to the signal output terminal Vout2 via the amplifier circuit 26.

As described above, it is possible to implement a MOS transistor switch having the low on-resistance in the ON state and the small off-leak current in the OFF state by changing a connection destination of the back gate terminal of the NMOS transistor M21 simultaneously when the ON and OFF states of the NMOS transistor M21 are switched, and a semiconductor device using the same. Also, it is possible to implement a sample-and-hold circuit in which a voltage drop occurring in the switch decreases during sampling and an electric charge fluctuation due to a leak current of the switch is small during holding by use of the above-described MOS transistor switch.

The sample-and-hold circuit may be configured using the semiconductor device shown in the first preferred embodiment.

While preferred embodiments of the present invention have been described and illustrated above, it should be understood that these are examples of the present invention and are not to be considered as limiting. Additions, omissions, substitutions, and other modifications can be made without departing from the scope of the present invention. Accordingly, the invention is not to be considered as being limited by the foregoing description, and is only limited by the scope of the claims.

1. A semiconductor device comprising:
a MOS transistor switch configured to control passage and interruption of a signal by switching between an ON state and an OFF state;
a first switch connected between a back gate terminal of the MOS transistor switch and a source terminal of the MOS transistor switch; and
a second switch connected between the back gate terminal of the MOS transistor switch and a power supply voltage terminal, and wherein
if the MOS transistor switch is in the ON state, then the first switch is in the ON state and the back gate terminal of the MOS transistor switch is connected to the source terminal of the MOS transistor switch, and
if the MOS transistor switch is in the OFF state, then the second switch is in the ON state and the back gate terminal of the MOS transistor switch is connected to the power supply voltage terminal.

2. A semiconductor device comprising:
a MOS transistor switch configured to control passage and interruption of a signal by switching between an ON state and an OFF state; and
a variable voltage source connected to a back gate terminal of the MOS transistor switch,
and wherein
if the MOS transistor switch is in the ON state, then the variable voltage source outputs a first voltage to the back gate terminal so that a threshold voltage of the MOS transistor switch becomes lower than when the MOS transistor switch is in the OFF state, and
if the MOS transistor switch is in the OFF state, then the variable voltage source outputs a second voltage to the back gate terminal so that the threshold voltage of the MOS transistor switch becomes higher than when the MOS transistor switch is in the ON state.

3. A sample-and-hold circuit comprising:
the semiconductor device according to claim 1;
a capacitor configured to accumulate an electric charge corresponding to an input voltage; and
an output buffer configured to convert the electric charge accumulated in the capacitor into a voltage, and wherein
if the MOS transistor switch is in an ON state, then the capacitor accumulates the electric charge corresponding to the input voltage, and
if the MOS transistor switch is in an OFF state, then the capacitor retains the electric charge that has been accumulated in the capacitor.

4. A sample-and-hold circuit comprising:
the semiconductor device according to claim 2;
a capacitor configured to accumulate an electric charge corresponding to an input voltage; and
an output buffer configured to convert the electric charge accumulated in the capacitor into a voltage, and wherein
if the MOS transistor switch is in an ON state, then the capacitor accumulates the electric charge corresponding to the input voltage, and
if the MOS transistor switch is in an OFF state, then the capacitor retains the electric charge that has been accumulated in the capacitor.
